(19) United States
(12) Patent Application Publication
(10) Pub. No.: US 2026/0158560 A1
(43) Pub. Date: Jun. 11, 2026

(54) CUTTING TOOL HAVING HARD COATING WITH EXCELLENT WEAR RESISTANCE AND TOUGHNESS

(71) Applicant: KORLOY INC., Seoul (KR)

(72) Inventors: Jin Han GWON, Cheongju-si, Chungcheongbuk-do (KR); Seung Su AHN, Cheongju-si, Chungcheongbuk-do (KR); Je Hun PARK, Cheongju-si, Chungcheongbuk-do (KR); Seong Yeon AHN, Cheongju-si, Chungcheongbuk-do (KR); Yeong Ju JO, Cheongju-si, Chungcheongbuk-do (KR); Hyung Jin KIM, Cheongju-si, Chungcheongbuk-do (KR)

(21) Appl. No.: 18/705,757

(22) PCT Filed: Sep. 26, 2022
(86) PCT No.: PCT/KR2022/014335

§ 371 Date: Apr. 29, 2024

(30) Foreign Application Priority Data
Nov. 19, 2021 (KR) 10-2021-0160670

(51) Int. Cl. B23B 27/14; C23C 14/06

(52) U.S. Cl. CPC B23B 27/148; C23C 14/0617; B23B 2228/105

(57) ABSTRACT

A cutting tool having a hard coating capable of satisfying various physical properties such as wear resistance, toughness, oxidation resistance, and heat crack resistance in a well-balanced manner is described. In order to achieve the above purpose, an embodiment provides a cutting tool that includes a hard base material and a hard coating formed on the hard base material, wherein the hard coating has the structure in which two or more sub-coatings having the composition range represented by the following [Chemical formula 1] and being different in lattice constant are alternately laminated. [Chemical formula 1] Al_{(1-x-y-z)} TiₓZr_{y}Me_{z}CₐO_{b}N_{(1-a-b)} (0<x<0.48, 0<y≤0.8, 0<z≤0.25, Me includes at least one selected from Cr, Ta, Hf, Nb, V, Y, W, Mo, Si, and B, 0<a<0.03 and 0<b<0.03)).

### TECHNICAL FIELD

The present invention relates to a hard coating formed on a hard base material such as cemented carbide, cermet, ceramic, and cubic boron nitride used in a cutting tool, and more specifically, to a hard coating formed of an oxycarbonitride containing Al, Ti, Zr, and other metal elements adjacent to the upper surface of the hard base material.

### BACKGROUND ART

In order to improve cutting performance and lifespan, a method of depositing a thin film of TiN, TiAlN, AlN, or Al₂O₃, which is a hard coating, on a hard base material such as a cemented carbide, cermet, an end mill, and a drill is used.

Until the 1980s, attempts were made to improve cutting performance and lifespan by coating a cutting tool with TiN, but since heat of approximately 600° C. to 700° C. is generated during a general cutting process, in the late 1980s, the coating technology had evolved to use TiAlN, which has higher hardness and oxidation resistance than typical TiN, and in order to further improve wear resistance and oxidation resistance, an AlTiN thin film which is further added with Al has been developed. By forming an Al₂O₃ oxide layer additionally on the AlTiN thin film, the effect of improving high-temperature oxidation resistance and wear resistance has been obtained, but it has been found out that improvements in other physical properties such as bonding strength, toughness, and lubricity are also necessary.

Meanwhile, the physical properties of such a hard coating are most affected by the type and content of elements constituting the hard coating, and the hardness, toughness, oxidation resistance, heat resistance, lubricity and the like are different depending on the composition of the hard coating. In order to maximally satisfy physical properties of a hard coating which are required differently depending on materials to be cut, cutting conditions, tool types, tool parts, and the like with a single composition system, a multi-element thin film coating technology has continued to develop for several tens of years.

### DISCLOSURE OF THE INVENTION

### Technical Problem

The purpose of the present invention is to provide a cutting tool having a hard coating capable of satisfying various physical properties such as toughness, oxidation resistance, heat resistance, and lubricity as well as wear resistance in a balanced manner.

### Technical Solution

In order to achieve the above purpose, the present invention may provide a cutting tool including a hard base material and a hard coating formed on the hard base material, wherein the hard coating has the structure in which two or more sub-coatings having the composition range represented by the following [Chemical formula 1] and being different in lattice constant are alternately laminated.

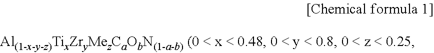

Me includes at least one selected from Cr, Ta, Hf, Nb, V, Y, W, Mo, Si, and B, 0<a<0.03 and 0<b<0.03)

In addition, in [Chemical formula 1] above, the range of z may be 0<z≤0.1.

In addition, in the cutting tool according to the present invention, the difference in (y+z) of [Chemical formula 1] above between the two or more sub-coatings may be less than 0.1.

In addition, in the cutting tool according to the present invention, [Chemical formula 1] above may further satisfy the relationships of (1-x-y-z)≥x, (1-x-y-z)≥z, x≥z, and (a+b)≤0.05.

In addition, in the cutting tool according to the present invention, in an upper portion or lower portion of the hard coating, one or more layers of a compound selected from a carbide, a nitride, an oxide, a carbonitride, an oxynitride, an oxycarbide, an oxycarbonitride, a boride, a boron nitride, a boron carbide, a boron carbonitride, a boron oxynitride, a boron oxocarbide, a boron oxocarbonitride, and a boron oxonitride containing one or more elements selected from the group consisting of Ti, Al, Cr, Ta, Hf, Nb, Zr, V, Y, W, Mo, Si, and B may be formed.

In addition, in the cutting tool according to the present invention, the hard coating may have a cubic or hexagonal structure, or may be a mixed texture of cubic, hexagonal or amorphous structures.

In addition, in the cutting tool according to the present invention, the thickness of the hard coating may be in the range of 0.02 μm to 20 μm, and the thickness of the hard sub-coating may be in the range of 1 nm to 50 nm.

### Advantageous Effects

According to the present invention, it is possible to obtain a hard coating having high wear resistance and excellent toughness at the same time by reducing residual stress while maintaining high hardness. In addition, the hard coating according to the present invention has greatly improved lubricity due to the influence of an added element, and has excellent oxidation resistance and heat crack resistant, so that a high-functional general-purpose cutting tool may be obtained.

### BRIEF DESCRIPTION OF THE DRAWINGS

FIG. 1 is a schematic diagram describing a structure of a cutting tool according to the present invention.

### BEST MODE FOR CARRYING OUT THE INVENTION

Hereinafter, in describing the present invention, when it is determined that detailed descriptions of related known functions or configurations may unnecessarily obscure the gist of the present invention, the detailed descriptions will be omitted. In addition, when a portion is said to ‘include’ any component, it means that the portion may further include other components rather than excluding the other components unless otherwise stated.

The present invention relates to a cutting tool including a hard base material and a hard coating formed on the hard base material, wherein the hard coating has the structure in which two or more sub-coatings having the composition range represented by the following [Chemical formula 1] and being different in lattice constant are alternately laminated.

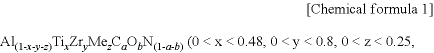

Me includes at least one selected from Cr, Ta, Hf, Nb, V, Y, W, Mo, Si, and B, 0<a<0.03 and 0<b<0.03)

The hard coating having the composition according to [Chemical formula 1] above includes Al, Ti, and Zr by default, and includes one or more selected from Cr, Ta, Hf, Nb, V, Y, W, Mo, Si, and B as other metal elements. Non-metal elements include C, N, and O.

In general, an oxide, carbide, nitride, or a mixed phase thereof containing Al, Ti, and Zr has high hardness, and thus, is widely used as a hard coating, but there is a problem in that toughness is poor due to residual stress generated during film formation. In order to solve the above-described problem, in the present invention, instead of a single hard coating, sub-coatings which have the same basic elements but differ only in crystal lattice constant are repeatedly and alternately laminated to minimize residual stress internally generated in a final hard coating, thereby increasing the toughness of the hard coating.

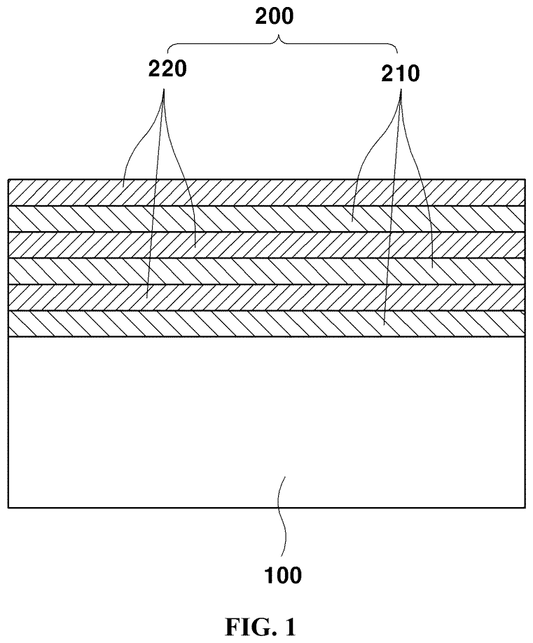

An example of a cutting tool according to the present invention described above is shown in FIG. 1. The cutting tool in FIG. 1 includes a hard coating 200 on a hard base material 100, wherein the hard coating includes sub-coatings 210 and 220 which are alternately laminated. The above-described sub-coatings have different lattice constants from each other, and for example, the crystal lattice constant of the sub-coating 210 may be greater than the crystal lattice constant of the sub-coating 220. However, the sub-coatings 210 and 220 both have a composition according to [Chemical formula 1] above.

In FIG. 1, two types of sub-coatings 210 and 220 are alternately laminated on each other, and the alternating stacking is illustrated as being repeated three times, but may be repeated one time, two times, or multiple times of four or more times, and the number of layers of the sub-coating 210 and the number of layers of the sub-coating 220 do not necessarily have to be the same. In addition, there may be three or four or more types of sub-coatings with different lattice constants, rather than two types thereof as shown in FIG. 1.

In addition, the hard coating of the present invention according to [Chemical formula 1] includes one or more selected from Cr, Ta, Hf, Nb, V, Y, W, Mo, Si, and B as other metal elements, wherein the wear resistance of the hard coating may be increased through controlling these elements, and the lubricity, oxidation resistance, and heat crack resistance may also be significantly improved depending on the combination and composition ratio of the elements with main elements constituting the coating. The value of z representing the ratio of Me, which is another metal element, in [Chemical formula 1] may be greater than 0 and 0.25 or less, and more preferably, may be greater than 0 and 0.1 or less. If the content of another metal element is too high, the ratio of other metal elements is relatively decreased, which may lower the hardness of the hard coating, so that it is preferable that the content of another metal element is maintained at a predetermined content or less.

In the present invention, two or more sub-coatings all have the composition of [Chemical formula 1], and in order to allow the lattice constants thereof different from each other, x, y, and z or a, b, and the like in [Chemical formula 1] may be adjusted to be different. Through the fine adjustment of the composition, it is possible to adjust the lattice constants to be slightly different.

In addition, in the hard coating according to the present invention, the difference in (y+z) of [Chemical formula 1] above between the two or sub-coatings may be less than 0.1.

In [Chemical formula 1], y and z respectively represent the composition ratio of Zr and Me, which another metal element, and if the difference in composition between sub-coatings is too large, the difference in lattice constants becomes large, and there is a risk of exhibiting an incoherent interface, so that peeling, chipping, and the like may easily occur due to the deterioration in bonding force between the sub-coatings. In addition, even if a coherent interface is maintained, the degree of misfit strain increases, thereby increasing the difference in residual stress, and as a result, residual stress of the sub-coatings may offset each other, and furthermore, residual stress greater than that of a single coating may be exhibited, which is not desirable. Therefore, it is preferable that the difference in the value of (y+z) between these sub-films is 0.1 or less.

In addition, in the hard coating according to the present invention, [Chemical formula 1] above may satisfy the relationships of (1-x-y-z)≥x, (1-x-y-z)≥z, x≥z, and (a+b)≤0.05.

In [Chemical formula 1], x, y, and z determine the content of metal elements Al, Ti, Zr, and Me, and when the value of (1-x-y-z), which represents the content of Al is greater than the value of x, which represents the content of Ti, the wear resistance and oxidation resistance are more excellent. Since Zr and Me, which is another metal element, are included, the crystallite size may be smaller than that of a typical AlTiN thin film, down to tens of nanometers. In addition, if the value of y, which represents the content of Zr, and the type of Me, which is another metal element, are adjusted, it is possible to mix even an amorphous structure inside the texture of a crystal structure, so that physical properties of the hard coating may be further improved.

In addition, when the value of (1-x-y-z), which represents the content of Al, and the value of x, which represents the content of Ti, are greater than the value of z, which represents the content of Me, another metal element, the deposition stability of a coating is high, the density of the coating is high, and the residual stress thereof is low. Another metal element included in the hard coating of the present invention is mostly a refractory metal element or metalloid element having a high melting point and low thermal conductivity, so that if the content thereof is higher than the content of Al and Ti, the melting and ionization of a PVD coating target are not facilitated, resulting in large and irregular coating particles, and reduced density of the coating. Accordingly, there are many defects generated in the coating, which may also act as a cause of an increase in residual stress. Therefore, it is preferable that the value of (1-x-y-z) and the value of x are greater than or at least equal to the value of z.

In addition, the value of a and the value of b determine the content of non-metal elements, and the sum thereof (a+b) represents the sum of carbon and oxygen. When trace amounts of carbon and oxygen are added to a nitride-based hard coating, the coating texture is refined and densified, and the shape of the coating surface is smoothened, thereby improving oxidation resistance and lubricity. However, if the value of (a+b) is greater than 0.05, the coating becomes brittle and the adhesion is greatly reduced, so that it is preferable that the value of (a+b) is 0.05 or less.

In addition, in the hard coating according to the present invention, in an upper portion or lower portion of the hard coating, one or more layers of a compound selected from a carbide, a nitride, an oxide, a carbonitride, an oxynitride, an oxycarbide, an oxycarbonitride, a boride, a boron nitride, a boron carbide, a boron carbonitride, a boron oxynitride, a boron oxocarbide, a boron oxocarbonitride, and a boron oxonitride containing one or more elements selected from the group consisting of Ti, Al, Cr, Ta, Hf, Nb, Zr, V, Y, W, Mo, Si, and B may be formed.

By additionally forming a compound layer composed of a carbide, a nitride, an oxide, or a combination thereof, which includes a metal element of the hard coating film, in the upper or lower portion of the hard coating, it is possible to diversify and optimize the physical properties of the hard coating depending on the environment in which the cutting tool is used.

In addition, the hard coating according to the present invention hard coating may have a cubic or hexagonal structure, or may be a mixed texture of cubic, hexagonal or amorphous structures.

The cubic structure has excellent toughness, and the hexagonal structure has excellent lubricity, and thus, when an amorphous structure is mixed with the crystal textures thereof, it is possible to obtain a hard coating having improved wear resistance, oxidation resistance, and heat crack resistance at the same time.

In addition, the thickness of the hard coating according to the present invention may be in the range of 0.02 μm to 20 μm, and the thickness of the hard sub-coating may be in the range of 1 nm to 50 nm.

If the thickness of the hard coating is less than 0.02 μm, it will not be possible to obtain sufficient wear resistance and oxidation resistance, and if the thickness is greater than 20 μm, a peeling problem caused by internal stress may occur. Therefore, it is preferable that the thickness of the hard coating is maintained in the range of 0.02 μm to 20 μm.

In addition, if the sub-coating is too thin, a crystal lattice is not exhibited, and if the sub-coating is too thick, a sufficient effect of offsetting residual stress is not obtained when the sub-coating is alternately laminated. Therefore, it is preferable that the thickness of the sub-coating is in the range of 1 nm to 50 nm.

Hereinafter, in order to describe the present invention in more detail, preferred embodiments according to the present invention will be described in more detail with reference to the accompanying drawings. However, the present invention is not limited to the embodiments described herein.

### EXAMPLES

### Preparation of Hard Coating

In Examples of the present invention, a coating having the structure shown in FIG. 1 was formed on the surface of a hard base material composed of a sintered body, such as cemented carbide, cermet, ceramic, or cubic boron nitride, by using arc ion plating, which is a physical vapor deposition (PVD) method.

A mother material was washed with wet microblasting and ultrapure water, and then mounted in a dried state along the circumference at a position away from a central axis on a rotary table in a coating furnace by a predetermined distance in a radial direction. The initial vacuum pressure in the coating furnace was reduced to 8.5×10−5 Torr or less, and the temperature was raised to 400° C. to 600° C., and then a pulse bias voltage of −200 V to −300V was applied to the rotating mother material while rotating on the rotary table under an Ar gas atmosphere to perform ion bombardment for 30 minutes to 60 minutes. The gas pressure for coating was maintained at 50 mTorr or less or 40 mTorr or less, and a substrate bias voltage of −20 V to −100V was applied during the coating.

As the hard base material, cemented carbide composed of WC having an average particle size of 0.8 μm and Co having a content of 10 wt. % was used. As a target for coating to form a hard coating on the hard base material, two or more types of AlTiZrMe arc targets per composition ratio and Me element were placed on 2 to 4 sides facing each other inside the coating furnace, and the coating was formed under the conditions of a bias voltage of −30 V to −60 V, an arc current of 100 A to 150 A, injection of N₂, O₂, and CH₄ as reaction gases, and a pressure of 2.7 Pa to 4.0 Pa. Here, AlTi, AlTiZr, and TiAlZrMe arc targets were additionally used to configure Comparative Examples of the present invention.

Examples and Comparative Examples of the present invention were prepared under the above-described conditions, and the basic information on the composition, thickness, hardness, and toughness of hard coatings corresponding thereto are shown in Table 1 below.

TABLE 1

| | | | | Thicknes | Hardness | Stress |
|---|---|---|---|---|---|---|
| Classification | Number | Thin film composition | | (μm) | (GPa) | (GPa) |
| Examples | 1-1 | Sub 1 | AlTiZrCrV(51:37:8:2:2)CON(1.5:1.5:97) | 4.0 | 35.4 | −1.1 |
| | | Sub 2 | AlTiZrCrV(62:18:2:16:2)CON(1.5:1.5:97) | | | |
| | 1-2 | Sub 1 | AlTiZrTaHf(51:37:8:2:2)CON(1.5:1.5:97) | 3.9 | 36.5 | −1.2 |
| | | Sub 2 | AlTiZrTaHf(52:34:2:6:7)CON(1.5:1.5:97) | | | |
| | 1-3 | Sub 1 | AlTiZrNbMo(51:37:8:2:2)CON(1.5:1.5:97) | 3.8 | 35.9 | −1.1 |
| | | Sub 2 | AlTiZrNbMo(54:36:2:4:5)CON(1.5:1.5:97) | | | |
| | 1-4 | Sub 1 | AlTiZrWY(51:37:8:2:2)CON(1.5:1.5:97) | 3.8 | 36.1 | −1.2 |
| | | Sub 2 | AlTiZrWY(55:37:2:4:2)CON(1.5:1.5:97) | | | |
| | 1-5 | Sub 1 | AlTiZrSi(52:38:8:2)CON(1.5:1.5:97) | 3.9 | 35.9 | −1.1 |
| | | Sub 2 | AlTiZrSi(54:36:2:8)CON(1.5:1.5:97) | | | |
| | 1-6 | Sub 1 | AlTiZrB(52:38:8:2)CON(1.5:1.5:97) | 4.0 | 35.8 | −1.0 |
| | | Sub 2 | AlTiZrB(54:36:2:8)CON(1.5:1.5:97) | | | |
| | 1-7 | Sub 1 | AlTiZrB(35:25:38:2)CON(1.5:1.5:97) | 4.1 | 34.3 | −0.8 |
| | | Sub 2 | AlTiZrB(41:29:22:8)CON(1.5:1.5:97) | | | |
| | 1-8 | Sub 1 | AlTiZrB(23:17:58:2)CON(1.5:1.5:97) | 4.2 | 33.5 | −0.9 |
| | | Sub 2 | AlTiZrB(29:21:42:8)CON(1.5:1.5:97) | | | |
| | 1-9 | Sub 1 | AlTiZrB(52:38:8:2)CON(1.5:1.5:97) | 4.0 | 35.9 | −1.1 |
| | | Sub 2 | AlTiZrB(53:43:2:2)CON(1.5:1.5:98) | | | |
| | | Sub 3 | AlTiZrB(54:36:2:8)CON(1.5:1.5:97) | | | |
| | 1-10 | Sub 1 | AlTiZrB(52:38:8:2)CON(1.5:1.5:97) | 4.0 | 36.3 | −1.2 |
| | | Sub 2 | AlTiZrB(53:43:2:2)CON(1.5:1.5:98) | | | |
| | | Sub 3 | AlTiZrB(54:36:2:8)CON(1.5:1.5:97) | | | |
| | | Sub 4 | AlTiZrB(53:43:2:2)CON(1.5:1.5:98) | | | |
| Comparative | 2-1 | Single | AlTi(60:40)N(100) | 4.0 | 30.3 | −1.5 |
| Examples | | layer | | | | |
| | 2-2 | Sub 1 | AlTi(67:33)N(100) | 3.9 | 32.6 | −1.4 |
| | | Sub 2 | AlTi(50:50)N(100) | | | |
| | 2-3 | Single | AlTi(60:40)CON(1.5:1.5:97) | 4.0 | 32.3 | −1.6 |
| | | layer | | | | |
| | 2-4 | Sub 1 | AlTi(67:33)CON(1.5:1.5:97) | 4.0 | 32.1 | −1.6 |
| | | Sub 2 | AlTi(50:50)CON(1.5:1.5:97) | | | |
| | 2-5 | Single | AlTiZr(55:40:5)CON(1.5:1.5:97) | 3.9 | 32.5 | −1.4 |
| | | layer | | | | |
| | 2-6 | Sub 1 | AlTiZr(53:39:8)N(100) | 3.9 | 33.7 | −1.2 |
| | | Sub 2 | AlTiZr(59:39:2)N(100) | | | |
| | 2-7 | Single | AlTiZr(55:40:5)CON(1.5:1.5:97) | 4.0 | 32.8 | −1.5 |
| | | layer | | | | |
| | 2-8 | Sub 1 | AlTiZr(53:39:8)CON(1.5:1.5:97) | 4.1 | 34.1 | −1.2 |
| | | Sub 2 | AlTiZr(59:39:2)CON(1.5:1.5:97) | | | |
| | 2-9 | Single | AlTiZrB(53:37:5:5)N(100) | 4.0 | 33.2 | −1.4 |
| | | layer | | | | |
| | 2-10 | Sub 1 | AlTiZrB(52:38:8:2)N(100) | 4.0 | 35.5 | −1.2 |
| | | Sub 2 | AlTiZrB(54:36:2:8)N(100) | | | |
| | 2-11 | Single | AlTiZrB(53:37:5:5)CON(1.5:1.5:97) | 3.9 | 33.0 | −1.3 |
| | | layer | | | | |
| | 2-12 | Sub 1 | TiAlZrB(52:38:8:2)CON(1.5:1.5:97) | 4.1 | 37.7 | −1.8 |
| | | Sub 2 | TiAlZrB(54:36:2:8)CON(1.5:1.5:97) | | | |

As confirmed in Table 1 above, the hard coatings of Examples generally have higher hardness but lower residual stress than the hard coatings of Comparative Examples. In general, a nitride-based hard coating deposited by arc ion plating tends to have increased residual stress as the hardness thereof increases.

However, when the residual stress is lowered while maintaining high hardness as in Examples of the present invention, it is possible to obtain a hard coating having excellent toughness as well as high wear resistance.

Meanwhile, the residual stress of a hard coating deposited by the physical vapor deposition (PVD) method usually exhibits a compressive stress (−), and it is known that the higher the compressive stress, the higher the impact resistance, that is, the toughness of the hard coating. However, the alloy technology, casting technology, heat treatment technology, and molding technology of a metal have greatly advanced in recent years, and the latest materials to be cut have become harder, tougher, and more heat-resistant, making it difficult to cut the same compared to typical materials to be cut. These difficult-to-cut materials increase the temperature of a cutting tool edge during processing, and cause chip welding, thereby increasing processing difficulty, resulting in decreasing productivity and shortening tool lifespan.

In processing a difficult-to-cut material, if the compressive stress of a hard coating is too high, the effect of reducing peeling or tear resistance of a thin film has a greater impact than the effect of improving impact resistance, and fine cracks or chipping on the surface of the hard coating caused by peeling immediately act as notches, resulting in consequently reducing the toughness of the hard coating.

Therefore, in order to obtain a hard coating having high wear resistance and excellent toughness at the same time, a suitable level of compressive stress is required.

### Evaluation of Cutting Performance

In order to evaluate the wear resistance, welding resistance, heat crack resistance, and chipping resistance of the hard coating prepared as shown in Table 1, a milling test was performed, and the evaluations were performed under the following conditions.
(1) Evaluation of wear resistance
Material to be cut: SM45C
Sample model number: SNMX1206ANN-MM
Cutting rate: 250 m/min
Cutting feed: 0.2 mm/tooth
Cutting depth: 2 mm

During the carbon steel processing, chemical friction wear is generally seen as the main wear type, and the hardness and oxidation resistance of the hard coating have a significant impact on the cutting performance.

### (2) Evaluation of Welding Resistance

Material to be cut: SKD11
Sample model number: ADKT170608PESR-MM
Cutting rate: 120 m/min
Cutting feed: 0.2 mm/tooth
Cutting depth: 5 mm

During the high-hardness steel processing, welding and chipping are generally seen as the main wear types, and the lubricity and peeling resistance of the hard coating have a significant impact on the cutting performance.

### (3) Evaluation of Heat Crack Resistance

Material to be cut: GCD600
Sample model number: SNMX1206ANN-MF
Cutting rate: 200 m/min
Cutting feed: 0.2 mm/tooth
Cutting depth: 2 mm

During the nodular cast iron processing, heat crack and chipping are generally seen as the main wear types, and the heat crack resistance of the hard coating has a significant impact on the cutting performance.

### (4) Evaluation of Chipping Resistance

Material to be cut: STS316
Sample model number: ADKT170608PESR-ML
Cutting rate: 120 m/min
Cutting feed: 0.12 mm/tooth
Cutting depth: 5 mm

During the stainless steel processing, chipping and damage caused by a strain hardening phenomenon are generally seen as the main wear types, and the peeling resistance and chipping resistance of the hard coating have a significant impact on the cutting performance.

The results of the evaluations under the above conditions are shown in Table 2 and Table 3 below.

TABLE 2

| | | Wear resistance | | Welding resistance | |
|---|---|---|---|---|---|
| | | Processing | | Processing | |
| Classification | Number | length (mm) | Wear type | length (mm) | Wear type |
| Examples | 1-1 | 8100 | Normal wear | 15000 | Normal wear |
| | 1-2 | 7500 | Normal wear | 11700 | Welded |
| | 1-3 | 7800 | Normal wear | 12000 | Welded |
| | 1-4 | 7200 | Normal wear | 13500 | Normal wear |
| | 1-5 | 7500 | Normal wear | 14700 | Normal wear |
| | 1-6 | 7200 | Normal wear | 15000 | Normal wear |
| | 1-7 | 6900 | Normal wear | 15300 | Normal wear |
| | 1-8 | 6900 | Normal wear | 16200 | Normal wear |
| | 1-9 | 7500 | Normal wear | 15000 | Normal wear |
| | 1-10 | 7800 | Normal wear | 15000 | Normal wear |
| Comparative | 2-1 | 4500 | Excessive wear | 8700 | Welded, |
| Examples | | | | | excessive wear |
| | 2-2 | 5100 | Excessive wear | 9000 | Welded, |
| | | | | | excessive wear |
| | 2-3 | 4500 | Excessive wear | 7200 | Thin film |
| | | | | | tearing |
| | 2-4 | 4800 | Excessive wear | 6900 | Thin film |
| | | | | | tearing |
| | 2-5 | 4800 | Excessive wear | 10800 | Welded |
| | 2-6 | 5100 | Excessive wear | 11400 | Welded |
| | 2-7 | 5100 | Thin film | 9000 | Thin film |
| | | | tearing, wear | | tearing, |
| | | | | | excessive wear |
| | 2-8 | 5700 | Thin film | 9600 | Welded |
| | | | tearing | | |
| | 2-9 | 5700 | Thin film | 8700 | Thin film |
| | | | tearing, wear | | tearing, welded |
| | 2-10 | 6600 | Welded | 12300 | Welded |
| | 2-11 | 5100 | Thin film | 8700 | Thin film |
| | | | tearing, | | tearing |
| | | | excessive wear | | |
| | 2-12 | 7200 | Thin film | 5400 | Thin film |
| | | | tearing | | tearing, welded |

TABLE 3

| | | Heat crack resistance | | Chipping resistance | |
|---|---|---|---|---|---|
| | | Processing | | Processing | |
| Classification | Number | length (mm) | Wear type | length (mm) | Wear type |
| Examples | 1-1 | 3600 | Normal wear | 4800 | Normal wear |
| | 1-2 | 3000 | Normal wear | 4500 | Thin film |
| | | | | | tearing |
| | 1-3 | 3000 | Normal wear | 5200 | Normal wear |
| | 1-4 | 3000 | Normal wear | 4500 | Thin film |
| | | | | | tearing |
| | 1-5 | 3900 | Normal wear | 5700 | Normal wear |
| | 1-6 | 4200 | Normal wear | 6000 | Normal wear |
| | 1-7 | 3600 | Normal wear | 6300 | Normal wear |
| | 1-8 | 3900 | Normal wear | 6000 | Normal wear |
| | 1-9 | 4200 | Normal wear | 6000 | Normal wear |
| | 1-10 | 4200 | Normal wear | 6000 | Normal wear |
| Comparative | 2-1 | 1500 | Excessive wear, | 3900 | Damaged |
| Examples | | | heat crack, | | |
| | | | chipping | | |
| | 2-2 | 1500 | Excessive wear, | 4200 | Damaged |
| | | | heat crack, | | |
| | | | chipping | | |
| | 2-3 | 1200 | Excessive wear, | 3000 | Damaged |
| | | | heat crack, | | |
| | | | chipping | | |
| | 2-4 | 1500 | Excessive wear, | 2700 | Damaged |
| | | | heat crack, | | |
| | | | chipping | | |
| | 2-5 | 2100 | Heat crack, | 3600 | Damaged |
| | | | chipping | | |
| | 2-6 | 2400 | Heat crack | 3900 | Chipping |
| | 2-7 | 1800 | Heat crack, | 3000 | Damaged |
| | | | chipping | | |
| | 2-8 | 2100 | Heat crack | 3000 | Damaged |
| | 2-9 | 2400 | Heat crack | 4200 | Chipping |
| | 2-10 | 2700 | Heat crack | 4500 | Thin film |
| | | | | | tearing |
| | 2-11 | 2100 | Heat crack, | 3900 | Chipping |
| | | | chipping | | |
| | 2-12 | 900 | Excessive wear, | 1800 | Damaged |
| | | | heat crack, | | |
| | | | chipping | | |

As confirmed in Table 2 and Table 3, the hard coatings of Examples generally have better cutting performance than the hard coatings of Comparative Examples. Even if the hard coatings have similar hardness, the cutting performance thereof may greatly vary depending on the composition and structure of the hard coatings. As can be seen from Examples, there is a slight difference in the cutting performance depending on the content of Zr, the type of Me elements, and the number of sub-coatings with different lattice constants.

Meanwhile, the 2-1, 2-2, 2-3, and 2-4 hard coatings of Comparative Examples have low hardness and high stress, and thus, are subjected to quick wear, and subjected to chipping and breakage at the beginning of processing. In addition, due to lack of lubricity and heat crack resistance, welding, thin film tearing, and heat cracking easily occur.

The 2-5, 2-6, 2-7, and 2-8 hard coatings of Comparative Examples contain Zr, but do not have the same level of hardness as the hard coatings of Examples, thereby having low wear resistance, so that if only C and O are contained without the ME element, the stress is rather increased, making it easier for thin film tearing, chipping, and breakage to occur.

The 2-9 and 2-11 hard coatings of Comparative Examples have the same average composition ratio as the hard coatings of Examples, but have a single-layered structure, thereby having high stress, and the 2-10 hard coating of Comparative Example does not contain C and O, and thus, has poor lubricity, thereby exhibiting lower cutting performance than the hard coatings of Examples.

The 2-12 hard coating of Comparative Example is a hard coating with a higher content of Ti than the content of Al, and thus, exhibits good wear resistance due to high hardness, but has high stress, and thus, is subjected to rapid thin film tearing, as well as very quick welding, chipping, and breakage.

Therefore, the cutting tool of the present invention is a cutting tool including a hard coating having a structure in which two or more sub-coatings having different lattice constants are alternately laminated while having a composition range represented by Al (1-x-y-z) TiₓZr_{y}Me_{z}CₐO_{b}N_{(1-a-b)} (0<x<0.48, 0<y≤0.8, 0<z≤0.25, Me includes at least one selected from Cr, Ta, Hf, Nb, V, Y, W, Mo, Si, and B, 0<a<0.03 and 0<b<0.03), and has various physical properties such as toughness, oxidation resistance, heat resistance, and lubricity as well as wear resistance in a balanced manner, thereby having excellent cutting performance in the processing of materials to be cut, such as carbon steel, high-hardness steel, nodular cast iron, and stainless steel, which are mainly used in the metal processing industry.

1. A cutting tool comprising:
a hard base material and a hard coating formed on the hard base material, wherein the hard coating has the structure in which two or more sub-coatings having the composition range represented by the following [Chemical formula 1] and being different in lattice constant are alternately laminated: 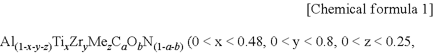
Me includes at least one selected from Cr, Ta, Hf, Nb, V, Y, W, Mo, Si, and B, 0<a<0.03 and 0<b<0.03)

2. The cutting tool of claim 1, wherein in [Chemical formula 1] above, the range of z is 0<z≤0.1.

3. The cutting tool of claim 1, wherein the difference in (y+z) of [Chemical formula 1] above between the two or more sub-coatings is less than 0.1.

4. The cutting tool of claim 1, wherein [Chemical formula 1] above further satisfies the relationships of (1-x-y-z)≥x, (1-x-y-z)≥z, x≥z, and (a+b)≤0.05.

5. The cutting tool of claim 1, wherein in an upper portion or lower portion of the hard coating, one or more layers of a compound selected from a carbide, a nitride, an oxide, a carbonitride, an oxynitride, an oxycarbide, an oxycarbonitride, a boride, a boron nitride, a boron carbide, a boron carbonitride, a boron oxynitride, a boron oxocarbide, a boron oxocarbonitride, and a boron oxonitride containing one or more elements selected from the group consisting of Ti, Al, Cr, Ta, Hf, Nb, Zr, V, Y, W, Mo, Si, and B are formed.

6. The cutting tool of claim 1, wherein the hard coating has a cubic or hexagonal structure, or is a mixed texture of cubic, hexagonal or amorphous structures.

7. The cutting tool of claim 1, wherein:
the thickness of the hard coating is in the range of 0.02 μm to 20 μm; and
the thickness of the hard sub-coating is in the range of 1 nm to 50 nm.
